(19) United States
(12) Patent Application Publication
(10) Pub. No.: US 2007/0262781 A1
(43) Pub. Date: Nov. 15, 2007

(54) APPARATUS AND METHOD TO DETECT MOISTURE IN POWER GENERATOR STATOR BARS

(76) Inventor: Donald J. Geisel, Clifton Park, NY (US)

Correspondence Address: SCHMEISER, OLSEN & WATTS, 22 CENTURY HILL DRIVE, SUITE 302, LATHAM, NY, 12110, US

(21) Appl. No.: 11/613,314

(22) Filed: Dec. 20, 2006

Related U.S. Application Data
(60) Provisional application No. 60/751,819, filed on Dec. 20, 2005.

(51) Int. Cl. G01R 27/28

(52) U.S. Cl. 324/649

(57) ABSTRACT

An apparatus for measuring moisture in a solid employs position feedback for an operator adjusted surface probe. This probe position feedback in the form of visual or audio signals allows an operator to more precisely position a surface probe when making such measurements. The visual or audio feedback will allow an operator to better place a moisture detection probe on a remote surface which may be obscured from the operator's direct line of sight.

This application is a non-provisional patent application of U.S. provisional patent application No. 60/751,819, filed Dec. 20, 2005 and entitled: “Improved Apparatus and Method to Detect Moisture in Power Generator Stator Bars”

### BACKGROUND OF THE INVENTION

1. Field of Invention

This invention relates to an apparatus and method for improved positioning of a sensor or indicator to measure moisture in a solid.

2. Related Art

U.S. Pat. No. 6,906,530 is a Method and Apparatus to Detect Moisture, invented by Donald J. Geisel, which is hereby incorporated by reference. The invention uses a parameter called “contact factor” as an indicator of moisture probe position. In U.S. Pat. No. 6,906,530 the specification teaches: “the magnitude of the test signal may also be determined and displayed as a contact factor, which may be used by an operator to confirm that the probe is making good surface contact with the insulation surrounding the stator bar”. The contact factor is quite useful in both placing and confirming probe position, especially in tight locations where one cannot actually see a target. However problems arise in aiding an operator in positioning of the moisture test probe.

### SUMMARY OF THE INVENTION

This invention is an apparatus for detecting position of an impedance based moisture detection apparatus, said apparatus comprising:

a probe;

a probe position indicator, operatively attached to said probe, wherein said probe position indicator indicates probe surface position while said moisture detection apparatus detects moisture from a surface into a volume being measured for moisture;

and

a signal, derived from a measured impedance of said moisture detection apparatus, for indicating surface position.

Another aspect of the invention is a method for measuring moisture from a surface into a volume comprising:

providing a probe having moisture detection apparatus;

positioning the probe on a surface over a volume being measured for moisture;

detecting a surface position of the probe with a probe position indicator; and

outputting the surface position of the probe using the probe position indicator.

This invention allows an operator to more easily use contact factor as a positioning aide of the probe. In particular, the contact factor signal, such as an analog signal, is manipulated via circuitry and converted into an external signal. This external signal may have two forms. The first is a simple voltage level which drives a position indicator such as an analog or digital meter. Such meter can be easily positioned such that an operator can view the meter needle, to look for a peak, as an indication of highest contact factor, indicating best moisture probe position. The second form or mode provides an audio signal for an operator to hear. Hence a user can listen to various tones, beats, clicks or signal levels as indication of optimal moisture probe position. Alternatively a vibration device could be utilized to allow an operator to feel vibration as a positioning indicator.

### BRIEF DESCRIPTION OF THE DRAWINGS

In order that those skilled in the art will be better able to practice the invention, reference will be made to the drawings, wherein:

FIG. 1 is a block diagram of the system with Analog Meter;

FIG. 2 is a block diagram of the system with Audio Speaker;

FIG. 3 is a block diagram of the Analog Meter with circuitry; and

FIG. 4 is a block diagram of the Audio Speaker with circuitry;

### DETAILED DESCRIPTION OF EMBODIMENTS

Although certain embodiments of the present invention will be shown and described in detail, it should be understood that various changes and modifications may be made without departing from the scope of the appended claims. The scope of the present invention will in no way be limited to the number of constituting components, the materials thereof, the shapes thereof, the relative arrangement thereof, etc., and are disclosed simply as an example of an embodiment. The features and advantages of the present invention are illustrated in detail in the accompanying drawing, wherein like reference numeral refer to like elements throughout the drawings. Although the drawings are intended to illustrate the present invention, the drawings are not necessarily drawn to scale.

FIG. 1 shows a Moisture Detection Device or probe 1, with a connecting cable 2 carrying signal or contact factor signal 5, to an external probe position indicator 3. The probe 1 may be a hand-held surface probe. The probe test surface 22 is shown which may be power generator stator bars. The probe position indicator 3, 4, 9 may be any type of portable indicator such as an analog meter, a digital meter such as an LCD, an LED, an audible indicator, a vibratory indicator or can transmit a wireless signal such as an RF signal to a remote device having any type of display or signal processing therein. In operation the moisture detection device employs a remote probe 1 to examine test target surface 22 of volume 30 for the presence of internal moisture 32. Probe surface 24 contacts test surface 22. Volume 30 may consist of power generator stator bars. In some circumstances, an operator cannot see or otherwise evaluate the correct position of such probe 1. Therefore the operator must generally rely on a displayed parameter, contact factor, normally displayed on the test unit. This parameter, contact factor, is commonly the magnitude of a signal 5 emerging from a test probe 1, relating to impedance of a surface measurement. The signal 5 may be discrete or continuous. However other signals can also be used to indicate proper probe contact. The signal 5, derived from a measured impedance of said moisture detection apparatus or probe 1, may be used for indicating surface position. These signals 5 may include real and imaginary signal components as well as any signal developed for such purpose. The invention provides a useful signal 5 to remotely move a meter needle for an operator to visualize optimal probe position. Such meter or indicator 3, 4, 9 can be easily placed in operator view. The indicator 3 or an analog meter which displays an output of the signal 5, may have a signal which may be proportional to probe positional flatness on a surface 22.

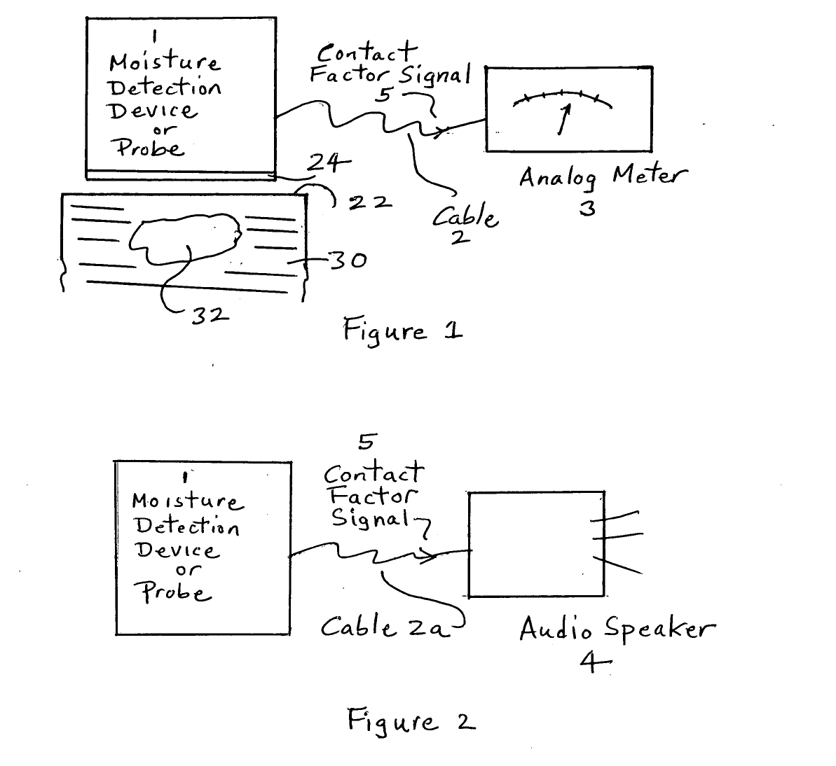

FIG. 2 shows a moisture detection device or probe 1, with a connecting cable 2a to an external and small portable speaker 4. In this mode the contact factor signal 5 is manipulated by any manner of signal processing to power an audio speaker 4. The operator listens to the speaker 4 for the correct audio sound as an indication of proper probe position. Sounds may be of any usable nature such as tones, levels, ticks or beeps or combination thereof, so an operator can be free to position a moisture detection probe in “tight locations” while only listening for the proper audio sound. As is the case for FIG. 1, other indicators or signals can be used in lieu of contact factor.

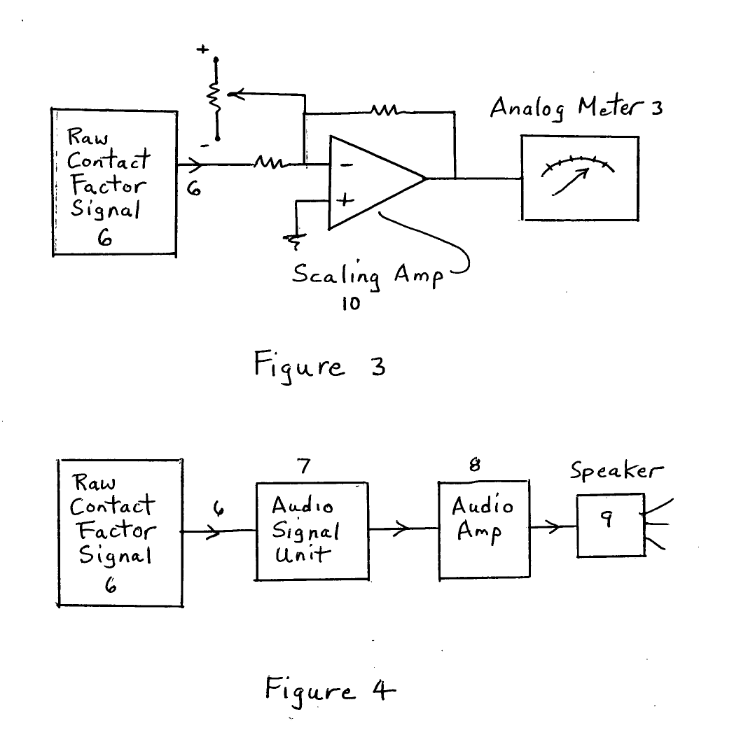

FIG. 3 shows a detail of FIG. 1. Here a scaling amplifier 10 with adjustable gain and offset may be used for signal processing to convert the raw contact factor signal 6 of moisture detection device or probe 1 to a level suitable to drive analog meter or indicator 3. Alternatively other signal processing may be used, such as a resistor divider network or other impedance transforming devices could be employed to drive an indicator 3.

FIG. 4 shows a detail of FIG. 2, where a raw contact factor signal 6 drives audio signal unit 7 and is amplified by audio amp 8 to drive remote speaker 9. The raw contact factor signal 6 of moisture detection device or probe 1 is fed to audio signal unit 7 where an output signal is generated that provides a usable tone, level, clicks or other audio variation so an operator can hear a sound to indicate correct moisture probe position. The probe position indicator includes an audio indicator to a emit sound, wherein said sound may vary with probe positional flatness. One example would be an audio tone which varies in pitch as a probe is correctly positioned on a surface. A variation would be to vary both pitch and amplitude of such tone to be loud and low in pitch when the moisture detection probe is correctly positioned. A further variation would be to vary the rate of tones or clicks such as a Geiger counter increases click rate in the presence of radiation.

A method is also disclosed for an impedance based moisture detection for measuring moisture from a surface into a volume. The method steps include, but are not limited to:

providing a probe 1 having moisture detection apparatus;

positioning the probe 1 on a surface 22 in contact with volume 30 being measured for moisture 32;

detecting a surface position of the probe 1 with a probe position indicator 3; and outputting the surface position of the probe using the probe position indicator.

Various modifications and variations of the described apparatus and methods of the invention will be apparent to those skilled in the art without departing from the scope and spirit of the invention. Although the invention has been described in connection with specific embodiments, outlined above, it should be understood that the invention should not be unduly limited to such specific embodiments. Various changes may be made without departing from the spirit and scope of the invention as defined in the following claims.

What is claimed:

1. Apparatus for detecting position of an impedance based moisture detection apparatus, said apparatus comprising:
a probe;
a probe position indicator, operatively attached to said probe, wherein said probe position indicator indicates probe surface position while said moisture detection apparatus detects moisture from a surface into a volume being measured for moisture;
and
a signal, derived from a measured impedance of said moisture detection apparatus, for indicating surface position.

2. The apparatus for detecting position of an impedance based moisture detection apparatus of claim 1, wherein the probe is a hand-held surface probe.

3. The apparatus for detecting position of an impedance based moisture detection apparatus of claim 1, wherein the probe position monitoring indicator further includes an analog meter which displays an output of the signal, wherein the signal is proportional to probe positional flatness on the surface.

4. The apparatus for detecting position of an impedance based moisture detection apparatus of claim 1, wherein the probe position indicator includes an audio indicator to a emit sound, wherein said sound varies with probe positional flatness.

5. The apparatus for detecting position of an impedance based moisture detection apparatus of claim 1, wherein the probe position indicator includes an audio indicator to emit a sound which varies in one of pitch and amplitude.

6. The apparatus for detecting position of an impedance based moisture detection apparatus of claim 1, wherein the probe further comprises a probe test surface with power generator stator bars.

7. The apparatus for detecting position of an impedance based moisture detection apparatus of claim 1, wherein the probe position indicator is remote from the impedance based moisture detection apparatus.

8. The apparatus for detecting position of an impedance based moisture detection apparatus according to claim 1, wherein the impedance may comprise real, or imaginary components of impedance or a combination thereof.

9. A impedance based moisture detection method for measuring moisture from a surface into a volume comprising:
providing a probe having moisture detection apparatus;
positioning the probe on a surface in contact with a volume being measured for moisture;
detecting a surface position of the probe with a probe position indicator; and
outputting the surface position of the probe using the probe position indicator.

10. A method of claim 9, further comprising, holding the probe in the user's hand.

11. A method of claim 9, further comprising, outputting the surface position onto an analog meter based on a signal proportional to probe positional flatness on the surface.

12. A method of claim 9, further comprising, adjusting the probe for improved surface flatness.

13. A method of claim 9, wherein the step of outputting the surface position of the probe further comprises outputting an audio signal that varies with probe positional flatness.

14. A method of claim 13 wherein the audio signal varies in at least one of pitch or amplitude.

15. A method of claim 9, further comprising providing a probe having a test surface with power generator stator bars.

16. A method of claim 9 wherein the position monitoring means is remote from the moisture detection apparatus.
